(19) United States
(12) Patent Application Publication
(10) Pub. No.: US 2023/0395749 A1
(43) Pub. Date: Dec. 7, 2023

(54) MICRO LIGHT-EMITTING ELEMENT, MICRO LIGHT-EMITTING ARRAY, TRANSFER METHOD, AND DISPLAY

(71) Applicant: Xiamen San'an Optoelectronics Co., Ltd., Xiamen (CN)

(72) Inventors: Zheng WU, Xiamen (CN); Chia-en LEE, Xiamen (CN)

(21) Appl. No.: 18/450,440

(22) Filed: Aug. 16, 2023

Related U.S. Application Data
(63) Continuation of application No. PCT/CN2021/077100, filed on Feb. 20, 2021.

(51) Int. Cl. H01L 33/22; H01L 33/00; H01L 33/62; H01L 33/08

(52) U.S. Cl. CPC H01L 33/22; H01L 33/0093; H01L 33/62; H01L 33/08

(57) ABSTRACT

A micro light-emitting element, a micro light-emitting array, a transfer method, and a display are provided. The micro light-emitting element has a side surface, a bottom surface and a top surface opposite to the bottom surface, and the top surface is a light-emitting surface. The micro light-emitting element includes a substrate arranged below the bottom surface and a transfer adhesive film covering the top surface. The transfer adhesive film does not exceed an edge of the top surface. During the laser removal of the transfer adhesive film, the adhesive adheres to the top surface and does not fall onto the substrate, thereby avoiding the generation of substrate dirt.

### TECHNICAL FIELD

The disclosure relates to the technical field of light-emitting devices, and more particularly to a micro light-emitting element, a micro light-emitting array, a transfer method, and a display.

### BACKGROUND

At present, a pick-and-place graphic selection scheme is adopted as a mainstream of massive transfer, and a corresponding structure of micro light-emitting diodes (also referred to as MicroLEDs or μLEDs) is a weakened structure with bridge arms, which is difficult to control the yield and has high cost.

### SUMMARY

In order to solve the problems mentioned in the background, reduce the difficulty of yield control, and reduce the production cost, the disclosure provides a micro light-emitting element. In order to describe the product structure clearly, the micro light-emitting element is defined to include a bottom surface, a top surface, and a side surface. The micro light-emitting element includes a semiconductor layer sequence, a first electrical connection layer, and a second electrical connection layer, with the side surface, the bottom surface and the top surface opposite to the bottom surface, the top surface is a light-emitting surface, and the light-emitting surface herein is a main light-emitting surface of the micro light-emitting element. The micro light-emitting element further includes a substrate disposed below the bottom surface and a transfer adhesive film covering the top surface. The top surface includes a first region and a second region, and the transfer adhesive film is only located in the first region. The first region is located in the second region, and the second region is located around the top surface. Structurally, the top surface has a stepped surface composed of the transfer adhesive film, and a distance between the transfer adhesive film and an edge of the top surface is in a range of 0.2 micrometers (μm) to 2 μm or 2 μm to 10 μm.

In an embodiment, the top surface of the micro light-emitting element includes one of a regular roughened surface and an irregular roughened surface, and the regular roughened surface is typically formed by patterning process.

In an embodiment, the transfer adhesive film is one of a continuous film and a discontinuous film. In a specific embodiment, the discontinuous film may have two or more separate patterns.

In an embodiment, the transfer adhesive film is a granular film, and the granular film with matching properties can be used as a light extraction structure when it is transparent.

In an embodiment, a thickness of the transfer adhesive film is in a range of 0.1 μm to 1 μm or no greater than 0.1 μm. Considering both transfer reliability and transparency, for some smaller sizes of chiplets, if the emphasis is on the reliability, the thickness of the transfer adhesive film is preferably 0.1 μm to 1 μm. In some applications that pursue the brightness, the thickness of the transfer adhesive film is preferably not greater than 0.1 μm.

In an embodiment, in order to match the ultraviolet (UV) laser decomposition of the transfer adhesive film and ensure the transparency to visible light, the transfer adhesive film is configured to transmit light with a wavelength ranging from 400 nanometers (nm) to 750 nm, and absorb at least partially light with a wavelength below 350 nm.

In an embodiment, an edge of the transfer adhesive film is inclined with an inclination angle in a range of 40° to 75°, thereby changing a path of light output.

In an embodiment, a length of any side of a surface of the transfer adhesive film in contact with the top surface is not less than 10 μm.

In an embodiment, a surface of the transfer adhesive film facing away from the semiconductor layer sequence has periodic grooves. The periodic grooves are a process structure after step-by-step laser decomposition of the transfer adhesive film, and a spacing between the periodic grooves is not more than 7 μm. If the spacing is too large, it is not conducive to the transfer of the chiplet after laser decomposition of the transfer adhesive film, which is prone to produce the chiplet rotation offset.

In an embodiment, a material of the transfer adhesive film includes one of polyimide and acrylic adhesive.

In an embodiment, a minimum side length of the micro light-emitting element is in a range of 50 μm to 100 μm or less than 50 μm.

In an embodiment, at least one of the first electrical connection layer and the second electrical connection layer is located on the bottom surface, and the micro light-emitting element is, for example, a flip chiplet or a vertical chiplet, and in some embodiments, it can also be a lateral chiplet.

In an embodiment, the substrate is a circuit board, and the bottom surface of the micro light-emitting diode is fixed on the circuit board.

In an embodiment, a thickness of the semiconductor layer sequence is in a range of 2.5 μm to 6 μm. In the field of micro light-emitting device transfer, a thickness of the epitaxial layer is usually thinner than that of the conventional sized chiplet, and the epitaxial layer is more susceptible to external force damage. Therefore, the product structure is matched and designed in the disclosure.

In the disclosure, a micro light-emitting array is provided and includes multiple micro light-emitting diodes. The micro light-emitting diode includes a bottom surface, a top surface, a side surface, a substrate disposed below the bottom surface and a transfer adhesive film covering the top surface. The transfer adhesive film has periodic grooves on a surface facing away from the semiconductor layer sequence, and a distance between the transfer adhesive film and an edge of the top surface is in a range of 0.2 μm to 2 μm or 2 μm to 10 μm.

In an embodiment, the transfer adhesive film has a roughened surface on a side close to the semiconductor layer sequence.

In an embodiment, a thickness of the transfer adhesive film is in a range of 0.1 μm to 1 μm or no greater than 0.1 μm.

In an embodiment, the transfer adhesive film is configured to transmit light with a wavelength ranging from 400 nm to 750 nm, and absorb at least partially light with a wavelength below 350 nm.

In an embodiment, the multiple micro light-emitting diodes have multiple wavelengths, and the multiple micro light-emitting diodes, for example, include red, green, blue (RGB) three color micro light-emitting diodes.

In an embodiment, an edge of the transfer adhesive film is inclined, with an inclination angle in a range of 40° to 75°.

In an embodiment, a side length of the transfer adhesive film in contact with the top surface is not less than 10 μm.

In an embodiment, the transfer adhesive film has periodic grooves on a surface facing away from the semiconductor layer sequence, and a spacing between the grooves is not greater than 7 μm.

In an embodiment, a material of the transfer adhesive film includes one of polyimide and acrylic adhesive.

In an embodiment, a minimum side length of the micro light-emitting diode is in a range of 50 μm to 100 μm or less than 50 μm.

In an embodiment, at least one of the first electrical connection layer and the second electrical connection layer is located on the bottom surface.

In an embodiment, the substrate is a circuit board, and the bottom surface of the micro light-emitting diode is fixed on the circuit board.

In an embodiment, a thickness of the semiconductor layer sequence is in a range of 2.5 μm to 6 μm.

The disclosure further provides a transfer method for a micro light-emitting array, which can produce the aforementioned micro light-emitting element and micro light-emitting array, specifically including the steps of:
step (1), providing a growth substrate, and making a semiconductor layer sequence on the growth substrate, the semiconductor layer sequence including a first semiconductor layer, a second semiconductor layer, and an active layer located between the first semiconductor layer and the second semiconductor layer;
step (2), making a separated semiconductor layer sequence structure, and the separated semiconductor layer sequence structure including a first mesa and a second mesa, and then making a first electrical connection layer and a second electrical connection layer respectively on the first mesa and the second mesa;
step (3), fixing a side of the semiconductor layer sequence facing away from the growth substrate on a first transfer substrate, and then removing the growth substrate; and
step (4), making a transfer adhesive film on a surface of the semiconductor layer sequence facing away from the first transfer substrate, removing some of the transfer adhesive film, and ensuring that the transfer adhesive film does not exceed an edge of the surface of the semiconductor layer sequence, where a distance between the transfer adhesive film and the edge of the semiconductor layer sequence is in a range of 0.2 μm to 2 μm or 2 μm to 10 μm, a thickness of the transfer adhesive film does not exceed 1 μm; fixing the semiconductor layer sequence on a second transfer substrate through the transfer adhesive film, then using laser to remove a part of the transfer adhesive film, peeling off the first transfer substrate, and exposing at least one of the first electrical connection layer and the second electrical connection layer.

In an embodiment, the method includes step (5) of completely removing the transfer adhesive film.

The disclosure discloses a display made using the transfer method of the micro light-emitting array mentioned above.

The disclosure discloses a display device with a micro light-emitting array, including multiple micro light-emitting diodes. The micro light-emitting diode includes a bottom surface, a top surface, a side surface, a circuit board arranged below the bottom surface and a transfer adhesive film covering the top surface. A distance between the transfer adhesive film and an edge of the top surface is in a range of 0.2 μm to 2 μm or 2 μm to 10 μm.

In an embodiment, the transfer adhesive film has periodic grooves on a surface facing away from the semiconductor layer sequence, and a spacing between the grooves is not greater than 7 μm.

In an embodiment, a minimum side length of the micro light-emitting diode is in a range of 50 μm to 100 μm or less than 50 μm.

In an embodiment, at least one of the first electrical connection layer and the second electrical connection layer is located on the bottom surface.

In an embodiment, a thickness of the semiconductor layer sequence is in a range of 2.5 μm to 6 μm.

The beneficial effects of the disclosure include providing the micro light-emitting diode chiplet structure with high transfer yield, and other beneficial effects of the disclosure will be explained in conjunction with detailed description of embodiments.

### BRIEF DESCRIPTION OF DRAWINGS

The accompanying drawings are included to provide a further understanding of the disclosure and constitute a part of the specification, and together with embodiments of the disclosure, they are used to explain the disclosure and do not constitute a limitation of the disclosure. In addition, the data in the drawings is a descriptive summary and not drawn to scale.

FIG. 1 illustrates a schematic cross-sectional view of a micro light-emitting array in the related art.

FIGS. 2-3 illustrate schematic cross-sectional views of a grown epitaxial film layer according to a first embodiment of the disclosure.

FIG. 4 illustrates a schematic cross-sectional view of a chip structure produced in the first embodiment of the disclosure.

FIGS. 5-9 illustrate schematic cross-sectional views of a first chiplet transfer process according to the first embodiment of the disclosure.

FIGS. 10-13 illustrate schematic cross-sectional views of a second chiplet transfer process according to the first embodiment of the disclosure.

FIG. 14 illustrates a schematic cross-sectional view of a third chiplet transfer process according to the first embodiment of the disclosure.

FIGS. 15-16 illustrate schematic cross-sectional and top views of a micro light-emitting element according to a second embodiment of the disclosure.

FIGS. 17-18 illustrate schematic cross-sectional views of the micro light-emitting element in some implementations according to the second embodiment of the disclosure.

FIG. 19 illustrates a schematic cross-sectional view of a micro light-emitting element according to a third embodiment of the disclosure.

FIG. 20 illustrates a schematic cross-sectional view of a micro light-emitting element according to a fourth embodiment of the disclosure.

FIGS. 21-22 illustrate schematic cross-sectional views of a micro light-emitting array according to a fifth embodiment of the disclosure.

FIG. 23 illustrates a schematic cross-sectional view of a micro light-emitting element according to a sixth embodiment of the disclosure.

FIGS. 24-25 illustrate schematic cross-sectional and top views of a display according to a seventh embodiment of the disclosure.

Description of reference signs are as follows:

111: first semiconductor layer; 111a: first region; 111b: second region; 111′: first mesa; 112: second semiconductor layer; 112′: second mesa; 121: first electrical connection layer; 122: second electrical connection layer; 210: transfer adhesive film; 220: bonding layer; 310: wafer; 320: growth substrate; 330: first transfer substrate; 340: second transfer substrate; 350: carrier board; 360: circuit board; 361: first conductive layer; 362: second conductive layer; circle (i.e., O): laser focusing position; a: tilt angle.

### DETAILED DESCRIPTION OF EMBODIMENTS

The following illustrates embodiments of the disclosure by means of specific concrete examples, and other advantages and effects of the disclosure can be easily understood by those skilled in the art from the content disclosed in the description. The disclosure can also be implemented or applied through different specific embodiments, and the details in the description can also be modified or altered based on different perspectives and applications without departing from the spirit of the disclosure.

It should be noted that the drawings provided in the embodiments only illustrate the basic concept of the disclosure in a schematic manner. Although the drawings only show the components related to the disclosure and are not drawn in accordance with the quantity, shape, and size of the components during actual implementation, the type, quantity, and proportion of each component can be changed, and the layout of the components may also be more complex.

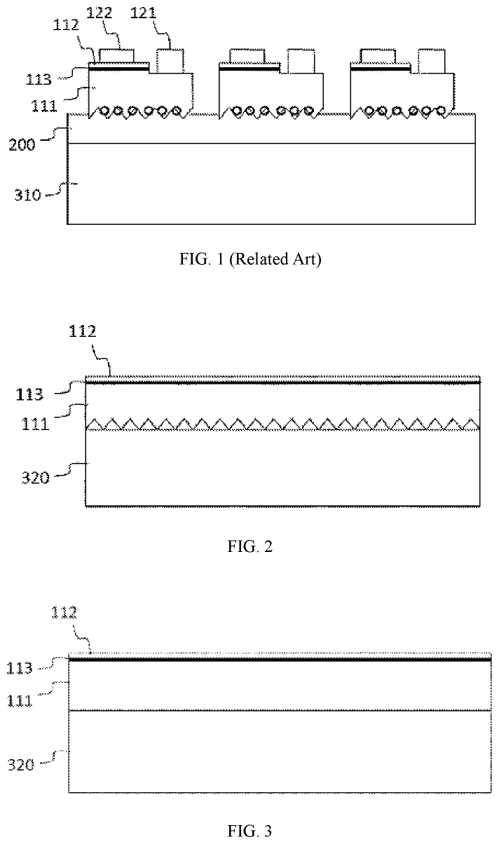

As shown in FIG. 1, a micro light-emitting array in the related art includes multiple micro light-emitting diodes. The micro light-emitting diode of the disclosure mainly refers to a light-emitting diode having a minimum side length in a range of 50 micrometers (μm) to 100 μm or less than 50 μm.

The micro light-emitting diode includes a semiconductor layer sequence including a first semiconductor layer 111, a second semiconductor layer 112, and an active layer 113 located between the first semiconductor layer 111 and the second semiconductor layer 112. A first electrical connection layer 121 and a second electrical connection layer 122 are electrically connected to the first semiconductor layer 111 and the second semiconductor layer 112, respectively. The micro light-emitting diode has a side surface and opposite bottom and top surfaces, with the top surface being a light emitting surface. At least one of the first electrical connection layer 121 and the second electrical connection layer 122 is a metal conductive layer, a non-metallic conductive layer, or a combination of the two. The metal conductive layer, for example, includes chromium (Cr), aluminum (Al), titanium (Ti), platinum (Pt), gold (Au), or nickel (Ni), and the non-metallic conductive layer, for example, includes indium tin oxide (ITO) or indium zinc oxide (IZO).

A transfer adhesive film 200 is disposed on the top surface of the micro light-emitting diode (where the top surface mainly refers to the product's light-emitting surface), the transfer adhesive film 200 is located on a wafer 310, which usually plays a role in fixing the chiplets in the related art. Since the conventional transfer adhesive film 200 is a continuous film layer, it is difficult to perform selective transfer. During selective transfer, laser separation of the epitaxial material layer of the micro light-emitting diode is often used. For example, the first semiconductor layer 111 is separated by laser, taking the first semiconductor layer 111 as a gallium nitride (GaN) based material as an example, using laser to decompose gallium nitride materials is prone to generating more gas in a short period of time, requiring a large amount of laser energy, and the difficulty of this problem is not obvious in the transfer process of conventional sized chiplets. The black circles in the FIG. 1 are the schematic laser decomposition points, while the thickness of the epitaxial layer of micron sized chiplets is usually 2.5 μm to 6 μm. During the transfer process, on the one hand, gas compression of the chiplets can easily cause problems such as chiplet displacement, resulting in poor transfer of the chiplets. On the other hand, the energy is high, and there is no effective support below the transfer of small chiplets, which can easily damage the epitaxial layer.

In the first embodiment of the disclosure, based on the above technical problems existing in the related art, the disclosure provides a transfer method for a micro light-emitting array.

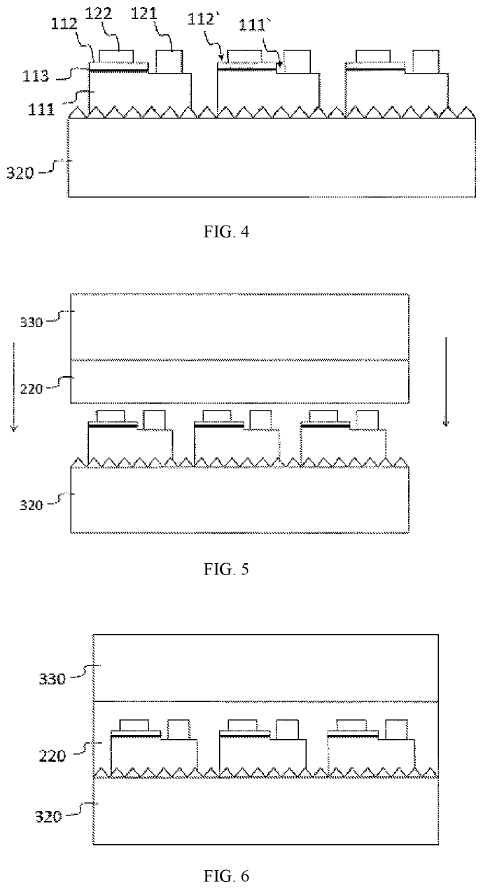

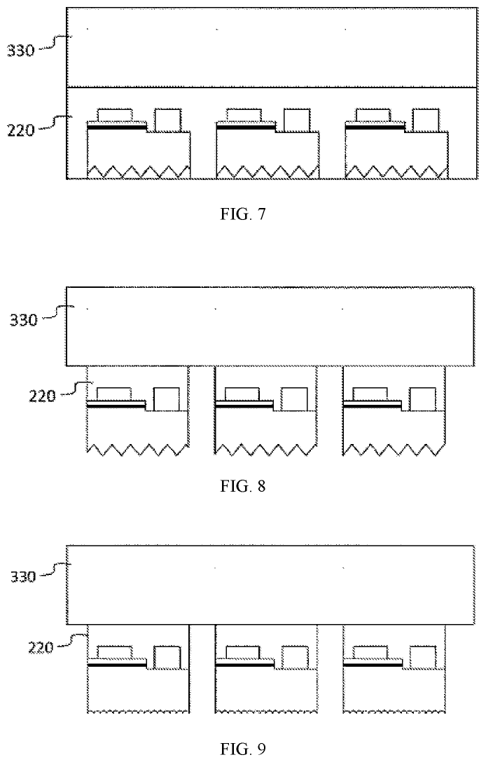

Specifically, a transfer method for a micro light-emitting array includes the following steps.
(1) As shown in FIGS. 2-3, a growth substrate 320 is provided, which is made of a common material such as sapphire, gallium arsenide, or silicon. According to the surface morphology of the substrate, the growth substrate 320 can be a flat sheet or a patterned substrate. A semiconductor layer sequence is formed on the growth substrate 320 by chemical vapor deposition, which includes: a first semiconductor layer 111, a second semiconductor layer 112, and an active layer 113 located between the first semiconductor layer 111 and the second semiconductor layer 112.
(2) As shown in FIG. 4, semiconductor layer sequence structures separated from each other are made, isolation trenches penetrating to the growth substrate are provided between the individual semiconductor layer sequences, and the separated semiconductor layer sequence structure includes a first mesa 111′ and a second mesa 112′. Specifically, the first mesa 111′ can be a P-type surface, and the second mesa 112′ can be an N-type surface, and a first electrical connection layer 121 and a second electrical connection layer 122 are respectively made on the first mesa 111′ and the second mesa 112′. In this embodiment, the first mesa 111′ and the second mesa 112′ are first made, and then the isolation trench between the semiconductor layer sequence structures is made. In some embodiments, the order can be adjusted.
(3) As shown in FIGS. 5-7, a side of the semiconductor layer sequence facing away from the growth substrate 320 is fixed on a first transfer substrate 330. The first transfer substrate 330 has a bonding layer 220, the bonding layer 220 is bonded to the semiconductor layer sequence, and then the growth substrate 320 is removed. In this embodiment, the fixing is realized through the bonding of adhesive materials.

As shown in FIG. 8, after removing the growth substrate 320, the adhesive materials between the chiplets are removed, achieving individual independence between the adhesive materials.

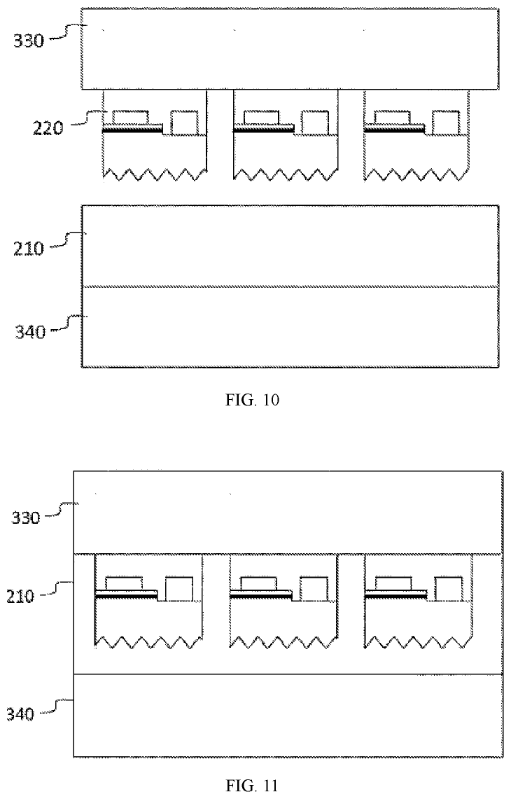

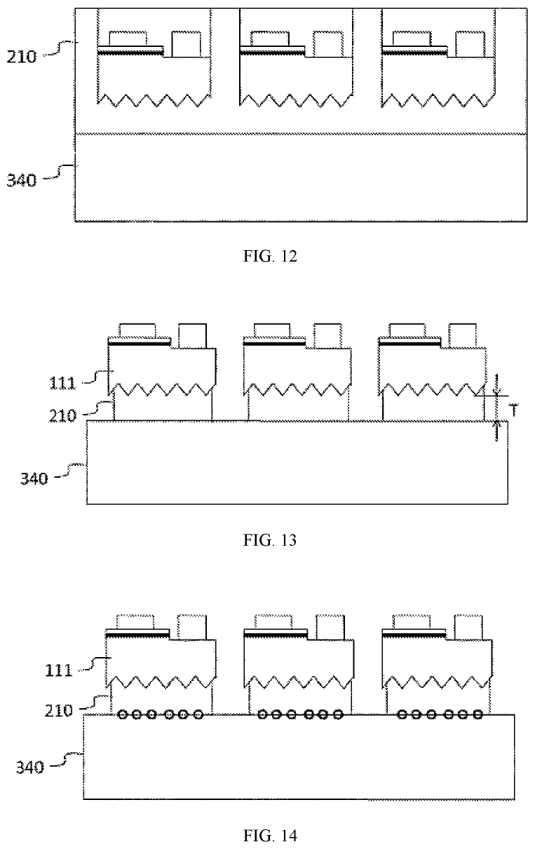

As shown in FIG. 9, in some implementations of this embodiment, taking the growth substrate 320 of a flat sheet as an example, the exposed surface of the semiconductor layer sequence after removing the growth substrate 320 can be roughened. In this embodiment, the exposed surface is the first semiconductor layer 111, and the roughening method includes wet etching or dry etching.
(4) As shown in FIGS. 10-12, a transfer adhesive film 210 is formed on the surface of the semiconductor layer sequence facing away from the first transfer substrate 330. For example, in this embodiment, by pressing the first semiconductor layer 111 into the transfer adhesive film 210 fixed on the second transfer substrate 340, the micro light-emitting diode is fixed on the second transfer substrate 340 through the transfer adhesive film 210, and then the first transfer substrate 330 is removed, which realizes that the micro light-emitting diode is transferred from the first transfer substrate 330 to the second transfer substrate 340 with the electrode surface of the micro light-emitting diode upside down. The material of the transfer adhesive film 210 includes polyimide or acrylic adhesive. The laser in the ultraviolet (UV) range passes through the sapphire material, and the material of the transfer adhesive film 210 can be decomposed under low energy to protect the epitaxial layer from laser damage.

As shown in FIG. 13, partial removal of the transfer adhesive film 210 can be achieved by etching, including dry etching or wet etching. In this embodiment, dry directional etching is used. After the removal process, the coverage surface of the transfer adhesive film 210 does not exceed the edge of the surface of the semiconductor layer sequence. The transfer adhesive film has a step surface, the transfer adhesive film is covered in the first region of the surface of the semiconductor layer sequence, and the transfer adhesive film is removed from the second region on the periphery. A distance between the transfer adhesive film 210 and the edge of the surface of the semiconductor layer sequence is in a range of 0.2 μm to 2 μm or 2 μm to 10 μm. The edge of the transfer adhesive film 210 on the top surface of the micro light-emitting element has grooves, achieving separation between individuals of the transfer adhesive film 210 and limiting the individuals of transfer adhesive film 210 within the surface of the first semiconductor layer 111. The thickness of the transfer adhesive film 210 is not greater than 500 nm. During the transfer process, even the very thin transfer adhesive is not easily dropped due to vibration, and one side of the transfer adhesive film 210 is completely bonded to the first semiconductor layer 111 to provide an adhesive force guarantee. After the removal process, the first electrical connection layer 121 and/or the second electrical connection layer 122 are exposed.

In this embodiment, to simplify the description, the top surface is the first semiconductor layer 111. In some embodiments, the top surface may include other materials, such as a transparent insulation layer or an insulating reflective layer.

In some implementations of this embodiment, a micro light-emitting array composed of multiple micro light-emitting diodes is bonded onto the circuit board.

As shown in FIG. 14, in some implementations of this embodiment, the method further includes step (5) of decomposing the transfer adhesive film 210 by laser and forming a groove on one side of the transfer adhesive film 210 close to the second transfer substrate 340. The circles in the FIG. 14 represent the area where the laser acts, and the area is located at the interface between the transfer adhesive film 210 and the second transfer substrate 340. The transfer adhesive film 210 is separated from the second transfer substrate 340 together with the micro light-emitting diode. In this step, the wavelength of the laser is the UV range of the non-visible light, and the transfer adhesive film 210 transmits the excited light with a wavelength in a range of 400 nm to 750 nm. The material of the transfer adhesive film 210, for example, is the polyimide or acrylic adhesive proposed in the above step, to avoid the reduction of the light extraction efficiency caused by the absorption of the transfer adhesive film during the application, while at least part of the light with the absorption wavelength below 350 nm can be fully decomposed by the laser in the UV range, thereby avoiding the laser damage to the semiconductor layer sequence.

In some embodiments, the transfer adhesive film 210 fixed on a circuit board or other carrier is separated from the second transfer substrate 340 together with the micro light-emitting diode, and then all the transfer adhesive film 210 on the surface of the micro light-emitting diode is removed.

In some embodiments, the transfer method of this embodiment is used to produce display chiplets in the display.

In the second embodiment of the disclosure, in order to improve the transfer efficiency or brightness of the micro light-emitting diode, a micro light-emitting diode is provided, with a minimum side length in a range of 50 μm to 100 μm or less than 50 μm. In this embodiment, the minimum side length of 50 μm of the micro light-emitting diode is used.

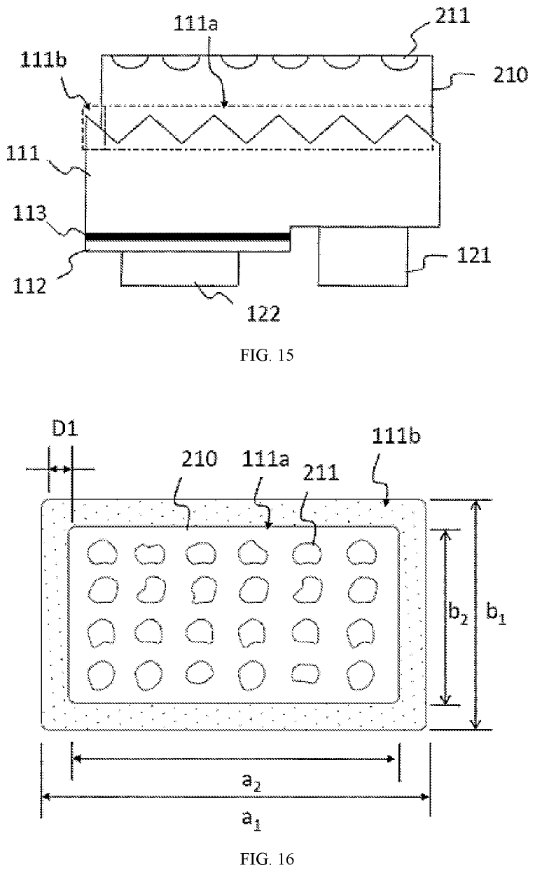

As shown in FIGS. 15 and 16, a micro light-emitting diode includes a semiconductor layer sequence, a first electrical connection layer 121 and a second electrical connection layer 122. The semiconductor layer sequence includes a first semiconductor layer 111, a second semiconductor layer 112, and an active layer 113 located between the first semiconductor layer 111 and the semiconductor layer 112. The micro light-emitting diode has a side surface, opposite bottom and top surfaces, and the top surface is the light-emitting surface. In some embodiments, the bottom surface of the micro light-emitting diode is fixed on a circuit board.

From a top view, the transfer adhesive film 210 is located in a first region 111a on the top surface of the micro light-emitting diode. The top surface also includes a second region 111b, the first region 111a is located in the second region 111b, and the second region 111b is located at the edge of the top surface. The top surface of the micro light-emitting diode has a step formed by the transfer adhesive film 210, and has a protrusion formed by the transfer adhesive film 210. The transfer adhesive film 210 shall not exceed the edge of the top surface (as shown in FIGS. 15 and 16, a lower surface of the transfer adhesive film 210 in contact with the top surface of the micro light-emitting diode and an upper surface facing from the top surface of the micro light-emitting diode shall not exceed the edge of the top surface, and a horizontal distance between the edge of the upper surface of the transfer adhesive film 210 and the edge of the top surface of the micro light-emitting diode, and a horizontal distance between the edge of the lower surface edge of the transfer adhesive film 210 and the edge of the top surface of the micro light-emitting diode are both non-zero). It should be noted that the edge not exceeding the top surface means that the projection of the transfer adhesive film 210 is located within the top surface mainly composed of the first semiconductor layer 111 in the top view of the product in the vertical direction. Specifically, the distance D1 between the transfer adhesive film 210 and the edge of the top surface (i.e., the horizontal distance between the edge of the top surface and the edge of the lower surface and the horizontal distance between the edge of the top surface and the edge of the upper surface on the projection plane) is in a range of 0.2 μm to 2 μm or 2 μm to 10 μm.

When the transfer adhesive film 210 exceeds the edge of the top surface, debris is easily generated during the laser decomposition of the transfer adhesive film 210, resulting in contamination and performance degradation.

In order to solve the stress and light absorption problems of the transfer adhesive film layer 210, it is set that the thickness of the transfer adhesive film 210 is not greater than 1000 nm, and in an embodiment, the thickness of the transfer adhesive film 210 is less than 500 nm. In some embodiments, the thickness of the transfer adhesive film 210 is not greater than 100 nm to minimize the impact of the adhesive material's light absorption. The material of the transfer adhesive film 210 includes polyimide or acrylic adhesive. In some embodiments, in order to minimize the area size of the transfer adhesive film 210 as much as possible while ensuring the adhesion between the transfer adhesive film 210 and the micro light-emitting diode, for example, when the transfer adhesive film 210 accounts for less than 80% of the surface area of the first semiconductor layer 111, or when the contact area between the transfer adhesive film 210 and the surface of the first semiconductor layer 111 accounts for less than 80% of the overall projection area of the micro light-emitting diode, an irregular roughened structure or a regular pattern roughened structure on the surface of the first semiconductor layer 111 facing towards the transfer adhesive film 210 is formed.

In this embodiment, a surface of the transfer adhesive film 210 facing away from the top surface has periodic grooves 211, the periodic grooves 211 are located on the surface of the transfer adhesive film 210, and the grooves 211 are generated by laser decomposition of the adhesive material to achieve chiplet transfer. The spacing between the grooves 211 is not greater than 7 μm. If the spacing between grooves 211 is too large, it is difficult to achieve chiplet transfer and separation, and it is easy to cause the pulling and deviation of the adhesive material.

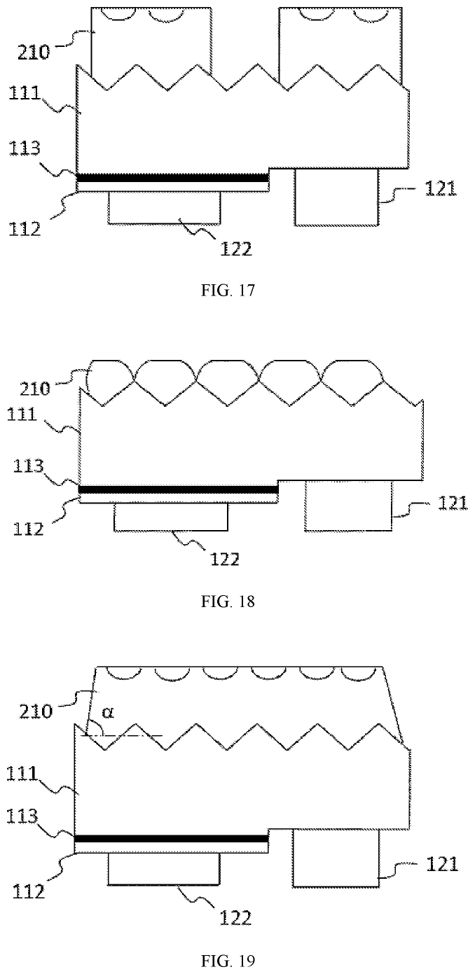

As shown in FIG. 17, in some embodiments, in order to release internal stress in the film layer and improve product reliability, the transfer adhesive film 210 is a patterned discontinuous film with intervals.

As shown in FIG. 18, the transfer adhesive film 210 is a discrete distributed particle film. For example, the transfer adhesive film 210 can be partially removed by etching to form a discrete distributed adhesive material. The refractive index of the adhesive material is in a range of 1 to 2.5, which has a certain light extraction effect. In some embodiments, the first semiconductor layer 111 is patterned, and the particles are located in the grooves of the pattern.

As shown in FIG. 19, in the third embodiment of the disclosure, a micro light-emitting element suitable for application in mobile phones or watch displays is provided. Due to the normal light intensity and privacy are emphasized in these application fields, and the side light emission is reduced, the difference between this embodiment and the second embodiment is that the edge of the transfer adhesive film 210 is inclined. In other words, the side of the transfer adhesive film 210 connected between the upper surface and the lower surface is inclined, so that the horizontal distance from the edge of the upper surface of the transfer adhesive film 210 to the edge of the top surface of the micro light-emitting element is non-zero. The inclination angle α is in a range of 40° to 80°, and in an embodiment, the inclination angle α is in a range of 45° to 75°.

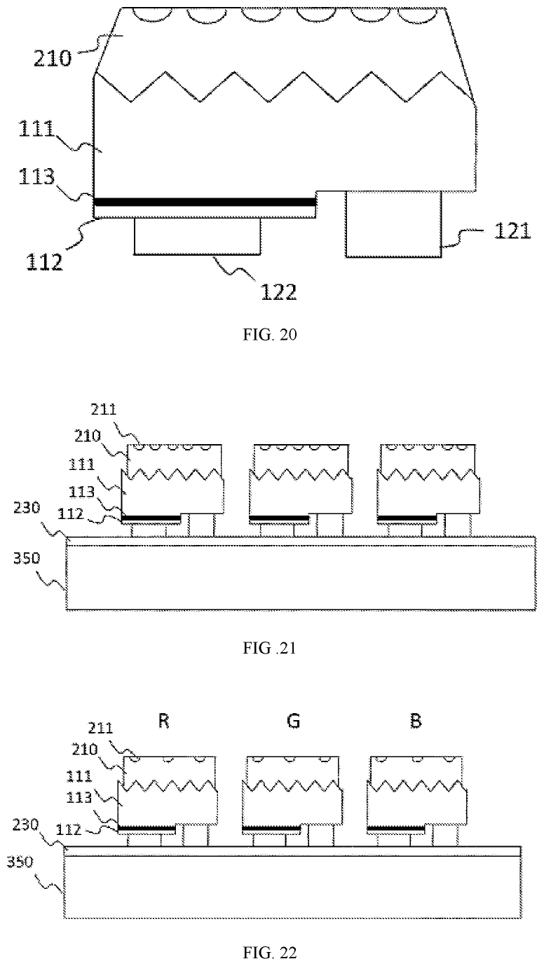

As shown in FIG. 20, in the fourth embodiment of the disclosure, as an optional implementation, a micro light-emitting element is provided, a transfer adhesive film covers a top surface of the micro light-emitting element, and the area of the surface of the transfer adhesive film contacting the semiconductor layer sequence is larger than the area of the surface of the transfer adhesive film facing away from the semiconductor layer sequence (for example, the vertical projection area of the lower surface of the transfer adhesive film contacting the micro light-emitting element on the top surface of the micro light-emitting element is greater than the vertical projection area of the lower surface of the transfer adhesive film on the top surface of the micro light-emitting element, instead of being equal to the vertical projection area of the upper surface of the transfer adhesive film on the top surface of the micro light-emitting element as shown in FIGS. 15 and 16). Using a trapezoidal transfer adhesive film can reduce the possibility of chipping.

As shown in FIGS. 21 and 22, in the fifth embodiment of the disclosure, a micro light-emitting array is provided, which includes multiple micro light-emitting diodes located on a bracket. The multiple micro light-emitting diodes can be light of the same color, light of different wavelengths, or light of different colors. For example, the multiple micro light-emitting diodes are composed of red, green, and blue micro light-emitting diodes. The micro light-emitting diode includes a bottom surface, a top surface, and a side surface, the bottom surface is the electrical connection surface, the top surface is the light emitting surface, and the transfer adhesive film 210 is independent of each other between the chiplets. The transfer adhesive film 210 is located on the top surface of the micro light-emitting diode, the transfer adhesive film 210 does not exceed the edge of the top surface, and the distance between the transfer adhesive film 210 and the edge of the top surface is in a range of 0.2 μm to 2 μm or 2 μm to 10 μm. When the transfer adhesive film 210 exceeds the edge of the top surface, debris is easily generated during the laser decomposition of the transfer adhesive film 210, and the debris is easily dropped onto the bracket, causing contamination and performance degradation. The bracket includes an adhesive layer 230 and a carrier board 350. The adhesive layer 230 can be an insulating adhesive film. The adhesive layer 230 can also be bonded metal such as solder paste. The carrier board 350 can be a circuit board used for bonding connection.

The transfer adhesive film 210 can transmit light with a wavelength in a range of 400 nm to 750 nm. In order to realize laser stripping and laser absorbing, the transfer adhesive film 210 at least partially absorbs light with a wavelength less than 350 nm. The material of the transfer adhesive film is polyimide or acrylic adhesive. In addition, in order to address the stress and light absorption issues of the transfer adhesive film 210, it is set that the thickness of the transfer adhesive film 210 is not greater than 1000 nm, and in an embodiment, the thickness of the transfer adhesive film 210 is less than 500 nm. In some embodiments, the thickness of the transfer adhesive film 210 is not greater than 100 nm, minimizing the impact of light absorption on the transfer adhesive film 210 as much as possible.

In order to minimize the area size of the transfer adhesive film 210 as much as possible while ensuring the adhesion between the transfer adhesive film 210 and the micro light-emitting diode, for example, when the transfer adhesive film 210 accounts for less than 80% of the surface area of the first semiconductor layer 111, or when the contact area between the transfer adhesive film 210 and the surface of the first semiconductor layer 111 accounts for less than 80% of the overall projection area of the micro light-emitting diode, an irregular roughened structure or a regular pattern roughened structure is made on the surface of the first semiconductor layer 111 facing towards the transfer adhesive film 210. In order to provide stable adhesion, the side length of the surface where the transfer adhesive film 210 contacts the top surface is not less than 10 μm.

In this embodiment, the transfer adhesive film 210 has periodic grooves 211 on the side facing away from the top surface. The periodic grooves 211 are located on the surface of the transfer adhesive film 210, and the grooves 211 are generated by laser decomposition of the adhesive material to achieve chiplet transfer. The spacing between the grooves 211 is not greater than 7 μm. If the spacing between grooves 211 is too large, it is difficult to achieve chiplet transfer and separation, and it is easy to cause the pulling and deviation of the adhesive material.

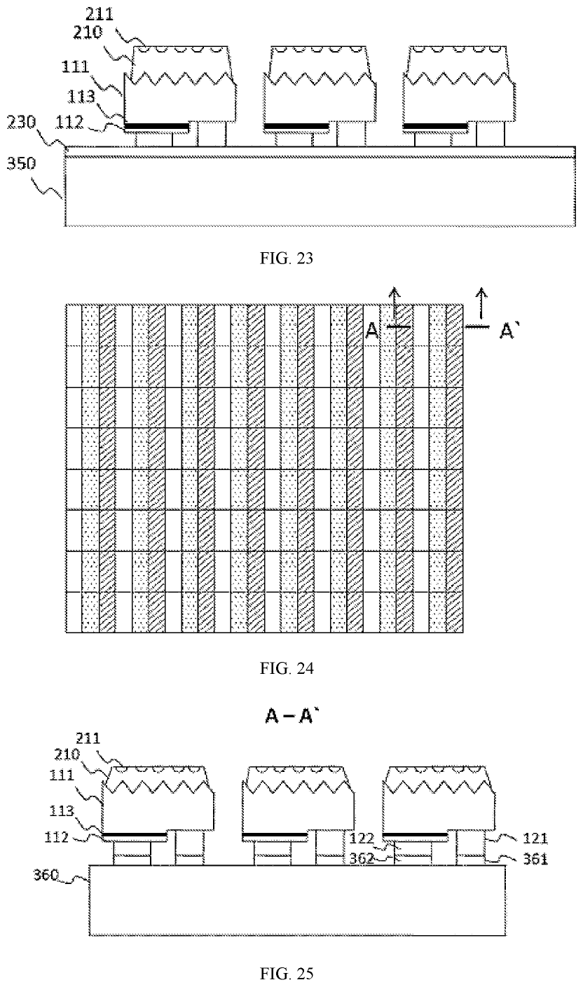

As shown in FIG. 23, in the sixth embodiment of the disclosure, the difference from the fifth embodiment 5 is that the edge of the transfer adhesive film 210 is inclined, with an inclination angle of 40° to 75°.

As shown in FIGS. 24 and 25, in the seventh embodiment of the disclosure, a display is provided, including a micro light-emitting array, and the micro light-emitting array includes multiple micro light-emitting diodes. The micro light-emitting diode includes a bottom surface, a top surface, and a side surface, in which the bottom surface is an electrical connection surface, the top surface is a light-emitting surface, and the micro light-emitting diode includes a first electrical connection layer 121, a second electrical connection layer 122, and a transfer adhesive film 210. The transfer adhesive film 210 is located on the top surface of the micro light-emitting diode, the transfer adhesive film 210 shall not exceed the edge of the top surface, and the distance between the transfer adhesive film 210 and the edge of the top surface is in a range of μm to 2 μm or 2 μm to 10 μm. The thickness of transfer adhesive film 210 shall not exceed 500 nm. The surface of the transfer adhesive film 210 facing away from the top surface is provided with periodic grooves 211, and the spacing between the grooves 211 of the micro light-emitting array is not greater than 7 μm.

A circuit board 360 is arranged on the bottom surface of the micro light-emitting array of the display, which includes a first conductive layer 361 electrically connected to the first electrical connection layer 121 and a second conductive layer 362 electrically connected to the second electrical connection layer 122. The micro light-emitting array is fixed on the circuit board 360.

The above is only the illustrated embodiments of the disclosure. It should be pointed out that for those skilled in the art, several improvements and replacements can be made without departing from the technical principles of the disclosure. These improvements and replacements should also be considered as the scope of protection of the disclosure.

What is claimed is:

1. A micro light-emitting element, comprising:
a semiconductor layer sequence, comprising a first semiconductor layer, a second semiconductor layer, and an active layer located between the first semiconductor layer and the second semiconductor layer;
a first electrical connection layer, electrically connected to the first semiconductor layer;
a second electrical connection layer, electrically connected to the second semiconductor layer;
wherein the micro light-emitting element has a side surface, a bottom surface and a top surface opposite to the bottom surface, and the top surface is a light-emitting surface; and
wherein the micro light-emitting element comprises a substrate arranged below the bottom surface and a transfer adhesive film covering a portion of the top surface, the top surface comprises a first region and a second region, the transfer adhesive film is located within the first region, and the second region surrounds the first region.

2. The micro light-emitting element according to claim 1, wherein a distance between the transfer adhesive film and an edge of the top surface is in a range of 0.2 micrometers (μm) to 2 μm, or 2 μm to 10 μm.

3. The micro light-emitting element according to claim 1, wherein the top surface comprises one of a regular roughened surface and an irregular roughened surface.

4. The micro light-emitting element according to claim 1, wherein the transfer adhesive film is one of a continuous film and a discontinuous film, a thickness of the transfer adhesive film is in a range of 0.1 μm to 1 μm or no greater than 0.1 μm, and a length of any edge of a surface of the transfer adhesive film in contact with the top surface is not less than 10 μm.

5. The micro light-emitting element according to claim 1, wherein the transfer adhesive film is configured to transmit light with a wavelength ranging from 400 nanometers (nm) to 750 nm and absorb at least partially light with a wavelength below 350 nm.

6. The micro light-emitting element according to claim 1, wherein an edge of the transfer adhesive film is inclined with an inclination angle in a range of 40° to 75°.

7. The micro light-emitting element according to claim 1, wherein the transfer adhesive film has periodic grooves on a surface facing away from the semiconductor layer sequence, and a spacing between the periodic grooves is less than or equal to 7 μm.

8. The micro light-emitting element according to claim 1, wherein a material of the transfer adhesive film comprises one of polyimide and acrylic adhesive.

9. The micro light-emitting element according to claim 1, wherein a minimum side length of the micro light-emitting element is in a range of 50 μm to 100 μm or less than 50 μm, and a thickness of the semiconductor layer sequence is in a range of 2.5 μm to 6 μm.

10. The micro light-emitting element according to claim 1, wherein at least one of the first electrical connection layer and the second electrical connection layer is located on the bottom surface.

11. The micro light-emitting element according to claim 1, wherein the substrate is a circuit board, and the bottom surface of the micro light-emitting element is fixed on the circuit board.

12. A micro light-emitting array, comprising:
a plurality of micro light-emitting diodes, wherein at least one of the plurality of micro light-emitting diodes comprises a semiconductor layer sequence, a first electrical connection layer, and a second electrical connection layer, with a bottom surface, a top surface, and a side surface; the semiconductor layer sequence comprises a first semiconductor layer, a second semiconductor layer, and an active layer located between the first semiconductor layer and the second semiconductor layer; and the first electrical connection layer is electrically connected to the first semiconductor layer, and the second electrical connection layer is electrically connected to the second semiconductor layer; and
wherein the at least one micro light-emitting diode comprises a substrate arranged below the bottom surface and a transfer adhesive film partially covering the top surface, the top surface comprises a first region and a second region, the transfer adhesive film is located within the first region, and the second region surrounds the first region.

13. The micro light-emitting array according to claim 12, wherein a distance between the transfer adhesive film and an edge of the top surface is in a range of 0.2 μm to 2 μm or 2 μm to μm.

14. The micro light-emitting array according to claim 12, wherein the transfer adhesive film has periodic grooves on a surface facing away from the semiconductor layer sequence, and a spacing between the periodic grooves is less than or equal to 7 μm.

15. The micro light-emitting array according to claim 12, wherein the transfer adhesive film is one of a continuous film and a discontinuous film, and a thickness of the transfer adhesive film is in a range of 0.1 μm to 1 μm or less than 0.1 μm; a length of any side of a surface of the transfer adhesive film in contact with the top surface is not less than 10 μm; the transfer adhesive film is configured to transmit light with a wavelength ranging from 400 nm to 750 nm, and absorb at least partially light with a wavelength below 350 nm.

16. A display, comprising a micro light-emitting array, wherein the micro light-emitting array comprises a plurality of micro light-emitting diodes, at least one of the plurality of micro light-emitting diodes comprises a bottom surface, a top surface, a side surface, a circuit board arranged below the bottom surface and a transfer adhesive film covering on the top surface, and an edge of the transfer adhesive film does not exceed an edge of the top surface.

17. The display according to claim 16, wherein the transfer adhesive film comprises a lower surface in contact with the top surface and an upper surface facing away from the top surface, a horizontal distance from an edge of the upper surface to the edge of the top surface is non-zero, and a vertical projection of the upper surface on the top surface is less than or equal to a vertical projection of the lower surface on the top surface.

18. The display according to claim 17, wherein the top surface comprises a first region and a second region, the second region surrounds the first region, the transfer adhesive film partially covers the top surface and is located within the first region, and a distance between an edge of the lower surface and an outer edge of the second region is in a range of 0.2 μm to 2 μm or 2 μm to 10 μm.

19. The display according to claim 17, wherein a side edge connected between the lower surface and the upper surface of the transfer adhesive film is inclined, and an area of the lower surface is greater than that of the upper surface.

20. The display according to claim 17, wherein the upper surface of the transfer adhesive film has periodic grooves, and a spacing between the periodic grooves is less than or equal to 7 μm; the transfer adhesive film is configured to transmit light with a wavelength ranging from 400 nm to 750 nm, and absorb at least partially light with a wavelength below 350 nm.
